(19) United States
(12) Patent Application Publication
(10) Pub. No.: US 2015/0054150 A1
(43) Pub. Date: Feb. 26, 2015

(54) SEMICONDUCTOR PACKAGE AND FABRICATION METHOD THEREOF

(71) Applicant: SILICONWARE PRECISION INDUSTRIES CO., LTD., Taichung (TW)

(72) Inventors: Cheng-Hsu Hsiao, Taichung (TW); Lung-Yuan Wang, Taichung (TW)

(73) Assignee: SILICONWARE PRECISION INDUSTRIES CO., LTD., Taichung (TW)

(21) Appl. No.: 14/085,101

(22) Filed: Nov. 20, 2013

(30) Foreign Application Priority Data
Aug. 22, 2013 (TW) 102129976

(51) Int. Cl. H01L 23/00

(52) U.S. Cl. CPC H01L 24/14; H01L 24/97
USPC 257/737; 438/107

(57) ABSTRACT

A method for fabricating a semiconductor package is disclosed, which includes: providing first and second packaging substrates, wherein a surface of the first packaging substrate has first conductive pads and first conductive posts formed on the first conductive pads, a surface of the second packaging substrate has second conductive pads and second conductive posts formed on the second conductive pads, and the surface of the second packaging substrate further has a semiconductor chip disposed thereon; disposing the first packaging substrate on the second packaging substrate in a manner that the first conductive posts correspond in position to and are electrically connected to the second conductive posts; and forming an encapsulant between the first and second packaging substrates for encapsulating the first and second conductive posts and the semiconductor chip, thereby effectively preventing solder bridging and increasing the product yield and reliability.

### BACKGROUND OF THE INVENTION

1. Field of the Invention

The present invention relates to semiconductor packages and fabrication methods thereof, and more particularly, to a stack-type semiconductor package and a fabrication method thereof.

2. Description of Related Art

Currently, electronic products are developed toward miniaturization, multi-function, high performance and high speed. Accordingly, R&D efforts are focused on stack-type semiconductor packages that integrate a plurality of semiconductor devices so as to meet the requirements of electronic products.

FIG. 1 is a schematic cross-sectional view of a conventional stack-type semiconductor package.

Referring to FIG. 1, the stack-type semiconductor package has a first semiconductor package 10 and a plurality of second semiconductor packages 11 stacked on and electrically connected to the first semiconductor package 10.

The first semiconductor package 10 has: a chip carrier 101; at least a semiconductor chip 102 disposed on an upper surface of the chip carrier 101 and electrically connected to the chip carrier 101 through a plurality of first conductive elements 103; a circuit board 104 disposed over the semiconductor chip 102 and supported on and electrically connected to the chip carrier 101 through a plurality of solder balls 105; an encapsulant 106 formed between the chip carrier 101 and the circuit board 104 for encapsulating the semiconductor chip 102 and the solder balls 105 while exposing an upper surface of the circuit board 104; and a plurality of second conductive elements 107 formed on a lower surface of the chip carrier 101 for electrically connecting the semiconductor chip 102 to an external element. The second semiconductor packages 11 are disposed on the upper surface of the circuit board 104 and electrically connected to the circuit board 104. As such, the first semiconductor package 10 and the second semiconductor packages 11 are integrated to form a stack-type semiconductor package.

However, as 110 counts increase and the distance between the solder balls 105 decreases, solder bridging easily occurs between the solder balls 105, thus reducing the product yield and reliability.

Therefore, there is a need to provide a semiconductor package and a fabrication method thereof so as to overcome the above-described drawbacks.

### SUMMARY OF THE INVENTION

In view of the above-described drawbacks, the present invention provides a method for fabricating a semiconductor package, which comprises the steps of: providing a first packaging substrate having opposite first and second surfaces and a second packaging substrate having opposite third and fourth surfaces, wherein the first surface of the first packaging substrate has a plurality of first conductive pads and a plurality of first conductive posts formed on the first conductive pads, the third surface of the second packaging substrate has a plurality of second conductive pads and a plurality of second conductive posts formed on the second conductive pads, and the third surface of the second packaging substrate further has a semiconductor chip disposed thereon; disposing the first packaging substrate on the second packaging substrate in a manner that the first conductive posts correspond in position to and are electrically connected to the second conductive posts; and forming an encapsulant between the first packaging substrate and the second packaging substrate for encapsulating the first conductive posts, the second conductive posts and the semiconductor chip.

In an embodiment, each of the first conductive posts has a solder bump formed thereon so as to be electrically connected to the corresponding second conductive post. Alternatively, each of the second conductive posts has a solder bump formed thereon so as to be electrically connected to the corresponding first conductive post.

After forming the encapsulant, the method can further comprise forming a plurality of conductive elements on the fourth surface of the second packaging substrate.

After forming the encapsulant, the method can further comprise performing a singulation process.

After forming the encapsulant, the method can further comprise disposing an electronic element on the second surface of the first packaging substrate. The electronic element can be a chip or a package.

The first conductive posts can be different in width from the second conductive posts. Preferably, the second conductive posts are greater in width than the first conductive posts.

The present invention further provides a semiconductor package, which comprises: a second packaging substrate having opposite third and fourth surfaces, wherein the third surface of the second packaging substrate has a plurality of second conductive pads and a plurality of second conductive posts formed on the second conductive pads; a semiconductor chip disposed on the third surface of the second packaging substrate; a first packaging substrate having opposite first and second surfaces and disposed on the second packaging substrate, wherein the first surface of the first packaging substrate has a plurality of first conductive pads and a plurality of first conductive posts formed on the first conductive pads, and the first packaging substrate is disposed on the second packaging substrate in a manner that the first conductive posts correspond in position to and are electrically connected to the second conductive posts through a plurality of solder bumps; and an encapsulant formed between the first packaging substrate and the second packaging substrate for encapsulating the first conductive posts, the second conductive posts and the semiconductor chip.

The semiconductor package can further comprise a plurality of conductive elements formed on the fourth surface of the second packaging substrate.

The semiconductor package can further comprise an electronic element disposed on the second surface of the first packaging substrate. The electronic element can be a chip or a package.

The first conductive posts can be different in width from the second conductive posts, Preferably, the second conductive posts are greater in width than the first conductive posts.

According to the present invention, both of the packaging substrates are provided with conductive posts such that the packaging substrates can be stacked on one another in a manner that the conductive posts of the packaging substrates correspond in position to and are electrically connected to one another, Since the conductive posts consume far less space than the conventional solder balls, the present invention effectively pre rents solder bridging and increases the product yield and reliability.

### BRIEF DESCRIPTION OF DRAWINGS

FIG. 1 is a schematic cross-sectional view of a conventional stack-type semiconductor package; and

FIGS. 2A to 2G are schematic cross-sectional views showing a semiconductor package and a fabrication method thereof according to the present invention, wherein FIG. 2A′ shows another embodiment of FIG. 2A, FIG. 2B′ shows another embodiment of FIG. 2B, and FIG. 2C′ shows another embodiment of FIG. 2C.

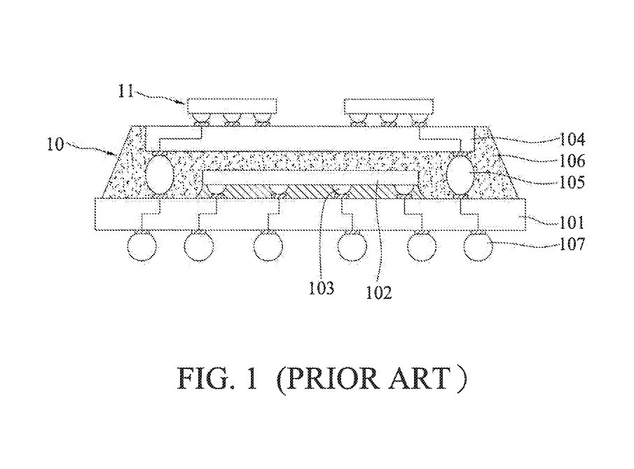

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “upper”, “lower”, “on”, “a” etc. are merely for illustrative purposes and should not be construed to limit the scope of the present invention.

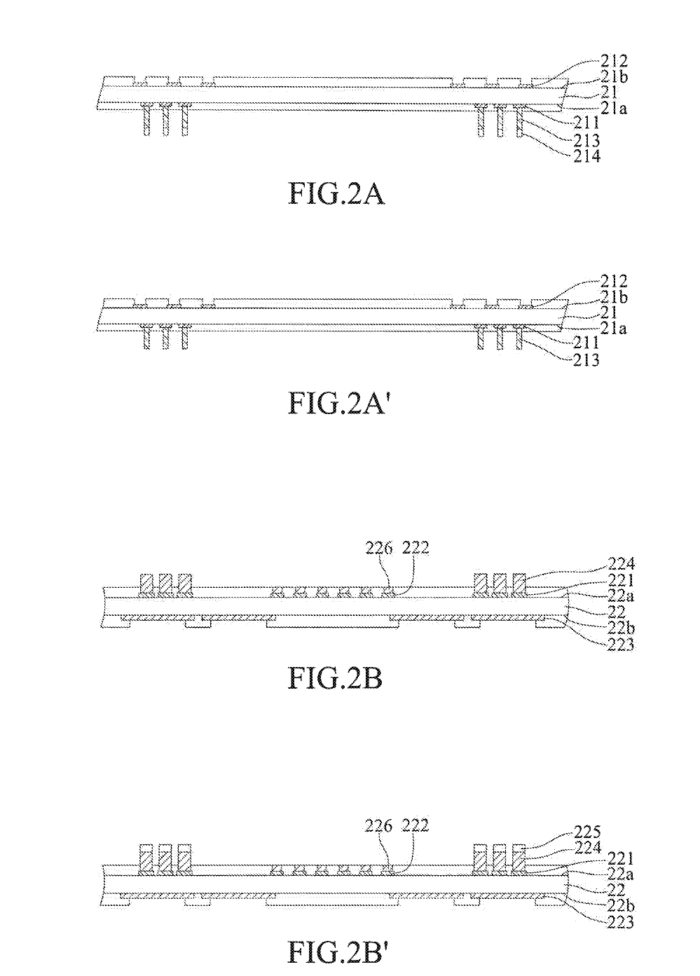

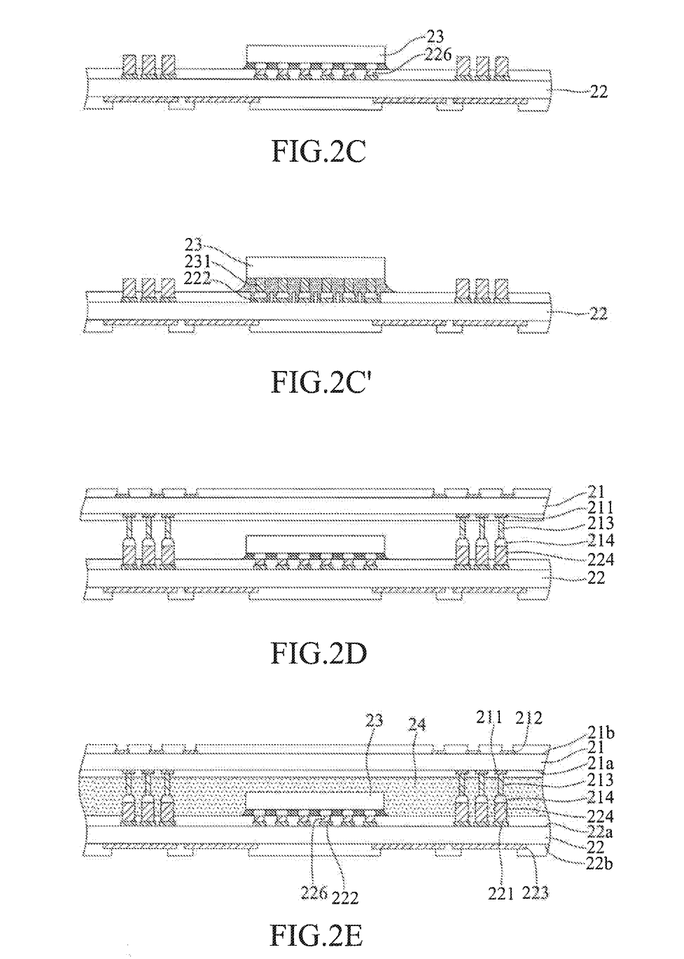

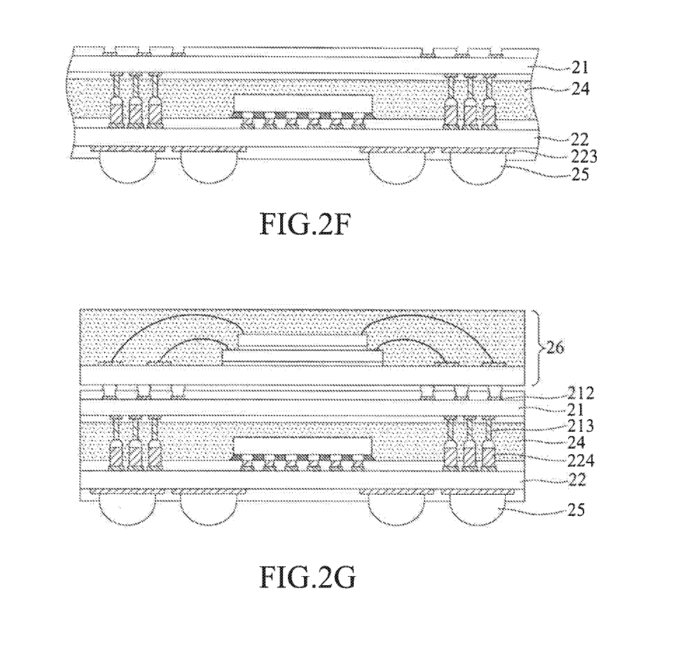

FIGS. 2A to 2G are schematic cross-sectional views showing a semiconductor package and a fabrication method thereof according to the present invention. Therein, FIG. 2A′ shows another embodiment of FIG. 2A, FIG. 2B′ shows another embodiment of FIG. 2B and FIG. 2C′ shows another embodiment of FIG. 2C.

Referring to FIG. 2A, a first packaging substrate 21 is provided. The first packaging substrate 21 has a first surface 21a having a plurality of first conductive pads 211 and a second surface 21b opposite to the first surface 21a and having a plurality of third conductive pads 212. A plurality of first conductive posts 213 are formed on the first conductive pads 211. Further, a plurality of solder bumps 214 are formed on the first conductive posts 213, respectively. The first conductive post 213 can be made of copper. In another embodiment, referring to FIG. 2A′, the first conductive post 213 are formed on the first conductive pads 211, but no solder bumps 214 are formed on the first conductive posts 213.

Referring to FIG. 2B, a second packaging substrate 22 is provided. The second packaging substrate 22 has a third surface 22a having a plurality of second conductive pads 221 and a plurality of fourth conductive pads 222, and a fourth surface 22b opposite to the third surface 22a and having a plurality of fifth conductive pads 223. A plurality of second conductive posts 224 are formed on the second conductive pads 221 and a plurality of third conductive posts 226 are formed on the fourth conductive pads 222. The second conductive posts 224 can be made of copper. In another embodiment, referring to FIG. 2B′, a plurality of solder bumps 225 are further formed on the second conductive posts 224, respectively.

Referring to FIG. 2C, a semiconductor chip 23 is flip-chip disposed on the third conductive posts 226 of the second packaging substrate 22. In another embodiment, the third conductive posts 226 can be omitted such that the semiconductor chip 23 is electrically connected to the second packaging substrate 22 through a plurality of solder bumps (not shown).

In another embodiment, referring to FIG. 2C′, no third conductive posts 226 are formed on the fourth conductive pads 222 of the second packaging substrate 22. But the semiconductor chip 23 has a plurality of fourth conductive posts 231 such that the semiconductor chip 23 is flip-chip disposed on the packaging substrate 22 in a manner that the fourth conductive posts 231 correspond in position to and are electrically connected to the fourth conductive pads 222.

Referring to FIG. 2D, the first packaging substrate 21 is disposed on the second packaging substrate 22 in a manner that the first conductive posts 213 correspond in position to and are electrically connected to the second conductive posts 224 through the solder bumps 214. In this process, a plurality of first packaging substrates 21 arranged in a unit or block such as in a 3×3 array, can be disposed on the second packaging substrate 22.

Referring to FIG. 2E, an encapsulant 24 is formed between the first packaging substrate 21 and the second packaging substrate 22 for encapsulating the first conductive posts 213, the second conductive posts 224 and the semiconductor chip 23.

Referring to FIG. 2F, a plurality of conductive elements 25 are formed on the fifth conductive pads 223 of the second packaging substrate 22.

Referring to FIG. 2G, a singulation process is performed and an electronic element 26 is disposed on and electrically connected to the third conductive pads 212 of the first packaging substrate 21. The electronic element 26 can be a package or a chip.

The first conductive posts 213 can have a width equal to or different from that of the second conductive posts 224. Preferably, the second conductive posts 224 are greater in width than the first conductive posts 213 so as to prevent overflow of the solder material between the first conductive posts 213 and the second conductive posts 224.

The present invention further provides a semiconductor package, which has: a second packaging substrate 22 having opposite third and fourth surfaces 22a, 22b, wherein the third surface 22a of the second packaging substrate 22 has a plurality of second conductive pads 221 and a plurality of second conductive posts 224 formed on the second conductive pads 221; a semiconductor chip 23 flip-chip disposed on the third surface 22a of the second packaging substrate 22; a first packaging substrate 21 having opposite first and second surfaces 21a, 21b and disposed on the second packaging substrate 22, wherein the first surface 21a of the first packaging substrate 21 has a plurality of first conductive pads 211 and a plurality of first conductive posts 213 formed on the first conductive pads 211, and the first packaging substrate 21 is disposed on the second packaging substrate 22 in a manner that the first conductive posts 213 correspond in position to and are electrically connected to the second conductive posts 224 through a plurality of solder bumps 214; and an encapsulant 24 formed between the first packaging substrate 21 and the second packaging substrate 22 for encapsulating the first conductive posts 213, the second conductive posts 224 and the semiconductor chip 23.

The semiconductor package can further comprise a plurality of conductive elements 25 formed on the fourth surface 22b of the second packaging substrate 22.

The semiconductor package can further comprise an electronic element 26 disposed on the second surface 21b of the first packaging substrate 21. The electronic element 26 can be a chip or a package.

The first conductive posts 213 can be different in width from the second conductive posts 224. Preferably, the second conductive posts 224 are greater in width than the first conductive posts 213.

According to the present invention, the first packaging substrate and the second packaging substrate respectively have the first conductive posts and the second conductive posts such that the first packaging substrate can be stacked on the second packaging substrate in a manner that the first conductive posts correspond in position to and are electrically connected to the second conductive posts, thereby forming a semiconductor package. Since the first and second conductive posts consume far less space than the conventional solder balls, the present invention effectively prevents solder bridging and increases the product yield and reliability.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A method for fabricating a semiconductor package, comprising the steps of:
providing a first packaging substrate having opposite first and second surfaces and a second packaging substrate having opposite third and fourth surfaces, wherein the first surface of the first packaging substrate has a plurality of first conductive pads and a plurality of first conductive posts formed on the first conductive pads, the third surface of the second packaging substrate has a plurality of second conductive pads and a plurality of second conductive posts formed on the second conductive pads, and the third surface of the second packaging substrate further has a semiconductor chip disposed thereon;
disposing the first packaging substrate on the second packaging substrate in a manner that the first conductive posts correspond in position to and are electrically connected to the second conductive posts; and
forming an encapsulant between the first packaging substrate and the second packaging substrate for encapsulating the first conductive posts, the second conductive posts and the semiconductor chip.

2. The method of claim 1, wherein ach of the first conductive posts has a solder bump formed thereon so as to be electrically connected to the e corresponding second conductive post.

3. The method of claim 1, wherein each of the second conductive posts has a solder bump formed thereon so as to be electrically connected to the corresponding first conductive post.

4. The method of claim 1, after forming the encapsulant, further comprising forming a plurality of conductive elements on the fourth surface of the second packaging substrate.

5. The method of claim 1, after forming the encapsulant, further comprising performing a singulation process.

6. The method of claim 1, after forming the encapsulant, further comprising disposing an electronic element on the second surface of the first packaging substrate.

7. The method of claim 6, wherein the electronic element is a chip or a package.

8. The method of claim 1, wherein the first conductive posts are different in width from the second conductive posts.

9. The method of claim 8, wherein the second conductive posts are greater in width than the first conductive posts.

10. A semiconductor package, comprising:
a second packaging substrate having opposite third and fourth surfaces, wherein the third surface of the second packaging substrate has a plurality of second conductive pads and a plurality of second conductive posts formed on the second conductive pads;
a semiconductor chip disposed on the third surface of the second packaging substrate;
a first packaging substrate having opposite first and second surfaces and disposed on the second packaging substrate, wherein the first surface of the first packaging substrate has a plurality of first conductive pads and a plurality of first conductive posts formed on the first conductive pads, and the first packaging substrate is disposed on the second packaging substrate in a manner that the first conductive posts correspond in position to and are electrically connected to the second conductive posts through a plurality of solder bumps; and
an encapsulant formed between the first packaging substrate and the second packaging substrate for encapsulating the first conductive posts, the second conductive posts and the semiconductor chip.

11. The package of claim 10, farther comprising a plurality of conductive elements formed on the fourth surface of the second packaging substrate.

12. The package of claim 10, further comprising an electronic element disposed on the second surface of the first packaging substrate.

13. The package of claim 12, wherein the electronic element is a chip or a package.

14. The package of claim 10, wherein the first conductive posts are different in width from the second conductive posts.

15. The package of claim 14, wherein the second conductive posts are greater in width than the first conductive posts.
